(19) United States
(12) Patent Application Publication
(10) Pub. No.: US 2018/0263304 A1
(43) Pub. Date: Sep. 20, 2018

(54) Heated Apparel System

(71) Applicant: Mohammad Maqbool, Garfield, NJ (US)

(72) Inventor: Mohammad Maqbool, Garfield, NJ (US)

(21) Appl. No.: 15/923,504

(22) Filed: Mar. 16, 2018

Related U.S. Application Data
(60) Provisional application No. 62/472,651, filed on Mar. 17, 2017.

(51) Int. Cl. A41D 13/005; A41D 3/00; A41D 1/00; A41D 19/00

(52) U.S. Cl. CPC A41D 13/0051; A41D 3/00; H01L 27/0635; A41D 19/0041; A41D 1/002

(57) ABSTRACT

A heated apparel system comprises: a garment, a printed circuit board (PCB), a heating element, a first power source, and a second power source. The PCB is coupled to one or both of the first and second power sources and comprises a first resistor coupled to a first junction; a second resistor coupled to said first junction and a second junction; a negatively doped bipolar junction transistor (BJT), having a base terminal, an emitter terminal, and a collector terminal, said base terminal coupled to said first junction and said emitter terminal coupled to said second junction; an integrated circuit coupled to said collector terminal of said BJT and said second junction; and an n-channel metal-oxide-semiconductor field-effect transistor (MOSFET), having a source terminal and a drain terminal, with the source terminal coupled to the integrated circuit and the drain terminal coupled to the heating element.

### CROSS-REFERENCE TO RELATED APPLICATION

This application claims priority to U.S. Provisional Application No. 62/472,651, filed on Mar. 17, 2017, which is incorporated by reference in its entirety.

### BACKGROUND

Outdoor apparel or clothing such as jackets and gloves are worn by users to keep warm during cooler seasons and cold environments. Sometimes, however, outdoor apparel is not designed to protect against excessive cold or wind, for example, while riding a motorcycle.

In order to provide additional warmth in these types of conditions, outdoor apparel is heated with electrical heating coils, which are powered by an external source. For a motorcycle rider, the external source is the 12-volt battery that powers the motorcycle.

The problem with the prior art outdoor garments is that once the motorcycle is turned off and the rider is no longer on the motorcycle, additional heating is not available because the garment is no longer connected to the power source.

There are other outdoor garments equipped with heating coils that can powered by portable power sources but those power sources are at 7.4 volts. Therefore, these garments will not work with 12-volt batteries.

As such, the user cannot wear the same heated garment on and off the motorcycle.

Therefore, a need exists for a heated apparel system that can operate at multiple voltages.

### SUMMARY

The following presents a simplified summary of some embodiments of the invention in order to provide a basic understanding of the invention. This summary is not an extensive overview of the invention. It is not intended to identify key/critical elements of the invention or to delineate the scope of the invention. Its sole purpose is to present some embodiments of the invention in a simplified form as a prelude to the more detailed description that is presented later.

The heated apparel system of the present invention comprises: (i) a garment; (ii) a printed circuit board (PCB); (iii) a heating element; (iv) a first power source; and (v) a second power source.

The PCB of the heated garment system is coupled to one or both of the first and second power sources and comprises (i) a first resistor coupled to a first junction; (ii) a second resistor coupled to said first junction and a second junction; (iii) a negatively doped bipolar junction transistor (BJT), having a base terminal, an emitter terminal, and a collector terminal, said base terminal coupled to said first junction and said emitter terminal coupled to said second junction; (iv) an integrated circuit coupled to said collector terminal of said BJT and said second junction; and (v) an n-channel metal-oxide-semiconductor field-effect transistor (MOSFET), having a source terminal and a drain terminal, said source terminal coupled to said integrated circuit and said drain terminal coupled to the heating element of the heated apparel system.

In a first embodiment, the present invention includes a heated apparel system comprising: a garment; a control unit; a heating element coupled to the control unit; and a power source coupled to the heating element, wherein the control unit controls the heating element to heat the garment from power provided by the power source. The control unit includes a printed circuit board (PCB). The power source is a battery. Alternatively or in addition, the power source may be rechargeable. Alternatively, the power source includes: a first power source; and a second power source; wherein the heating unit is coupled to at least one of the first and second power sources. The heating element includes: a first heating element coupled to the first power source; and a second heating element coupled to the second power source. The control unit includes: an integrated circuit; and a transistor, coupled to the integrated circuit, the heating element, and the power source, with the transistor driven by the integrated circuit to selectively control the heating element to generate heat. The transistor includes an n-channel metal-oxide-semiconductor field-effect transistor (MOSFET) having a source terminal and a drain terminal, with the source terminal coupled to the integrated circuit and the drain terminal coupled to the heating element. The control unit further comprises: a first junction; a second junction; a first resistor coupled to the first junction; a second resistor coupled to the first junction and the second junction; and a negatively doped bipolar junction transistor (BJT) having a base terminal, an emitter terminal, and a collector terminal, the base terminal coupled to the first junction and the emitter terminal coupled to the second junction, with the integrated circuit coupled to the collector terminal of the BJT and the second junction; wherein the integrated circuit and the BJT monitor a voltage of the source terminal to determine the available voltage from the power source to provide power to the heating element.

In another embodiment, the present invention includes a garment comprising: a garment material; a control unit; a heating element coupled to the control unit; and a power source coupled to the heating element, wherein the control unit controls the heating element to heat the garment material from power provided by the power source. The control unit includes a printed circuit board (PCB). The power source is a battery. Alternatively or in addition, the power source is rechargeable. The power source includes: a first power source; and a second power source; wherein the heating unit is coupled to at least one of the first and second power sources. The heating element includes: a first heating element coupled to the first power source; and a second heating element coupled to the second power source. The control unit includes: an integrated circuit; and a transistor, coupled to the integrated circuit, the heating element, and the power source, with the transistor driven by the integrated circuit to selectively control the heating element to generate heat. The transistor includes an n-channel metal-oxide-semiconductor field-effect transistor (MOSFET) having a source terminal and a drain terminal, with the source terminal coupled to the integrated circuit and the drain terminal coupled to the heating element. The control unit further comprises: a first junction; a second junction; a first resistor coupled to the first junction; a second resistor coupled to the first junction and the second junction; and a negatively doped bipolar junction transistor (BJT) having a base terminal, an emitter terminal, and a collector terminal, the base terminal coupled to the first junction and the emitter terminal coupled to the second junction, with the integrated circuit coupled to the collector terminal of the BJT and the second junction; wherein the integrated circuit and the BJT monitor a voltage of the source terminal to determine the available voltage from the power source to provide power to the heating element.

In still another embodiment, the present invention includes a method for heating a garment having a garment material, with the method comprising: providing a control unit, a heating element coupled to the control unit, and a power source coupled to the heating element; controlling the heating element using the control unit; and heating the garment material using the heating element from power provided by the power source. The method further comprising: providing an n-channel metal-oxide-semiconductor field-effect transistor (MOSFET) having a source terminal and a drain terminal, with the source terminal coupled to the control unit and the drain terminal coupled to the heating element; and driving the MOSFET using the control unit to selectively control the heating element to generate heat.

### BRIEF DESCRIPTION OF DRAWINGS

The foregoing summary, as well as the following detailed description of presently preferred embodiments of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a schematic of a first embodiment of the heated apparel system of the present invention.

FIG. 2 is a front view of the printed circuit board of the first embodiment of the heated apparel system of the present invention.

FIG. 3 is a front view of the first embodiment of the heated apparel system of the present invention without a garment.

FIG. 4 is a schematic of a second embodiment of heated apparel system of the present invention.

FIG. 5 is a front view of the printed circuit board of the second embodiment of the heated apparel system of the present invention.

FIG. 6 is a front view of the second embodiment of the heated apparel system of the present invention without a garment.

FIG. 7 is a front view of a pushbutton/LED light of a control switch of the heated apparel system of the present invention.

FIG. 8 if a front view of a portable 7.4-volt battery of the heated apparel system of the present invention.

FIG. 9 is a front view of a single power connector embodiment of the heated apparel system of the present invention with connectors exposed.

FIG. 10 is a front view of a dual power connector embodiment of the heated apparel system of the present invention with connectors exposed.

FIG. 11 is an alternative front view of the heated apparel system of FIG. 10.

FIG. 12 is a close-up view of the heated apparel system of FIG. 11.

FIG. 13 is an alternative view of the heated apparel system of FIG. 12 with connectors concealed.

To facilitate an understanding of the invention, identical reference numerals have been used, when appropriate, to designate the same or similar elements that are common to the figures. Further, unless stated otherwise, the features shown in the figures are not drawn to scale, but are shown for illustrative purposes only.

### DETAILED DESCRIPTION

Certain terminology is used in the following description for convenience only and is not limiting. The article “a” is intended to include one or more items, and where only one item is intended the term “one” or similar language is used. Additionally, to assist in the description of the present invention, words such as top, bottom, side, upper, lower, front, rear, inner, outer, right and left are used to describe the accompanying figures. The terminology includes the words above specifically mentioned, derivatives thereof, and words of similar import.

The heated apparel system of the present invention comprises: (i) a garment 100; (ii) a printed circuit board (PCB) 200; (iii) a heating element 300; (iv) a first power source; and (v) a second power source.

The PCB of the heated garment system is coupled to one or both of the first and second power sources and comprises (i) a first resistor 202 coupled to a first junction 204; (ii) a second resistor 206 coupled to said first junction 202 and a second junction 208; (iii) a negatively doped bipolar junction transistor (BJT) 210, having a base terminal 212, an emitter terminal 214, and a collector terminal 216, said base terminal 212 coupled to said first junction 204 and said emitter terminal 214 coupled to said second junction 208; (iv) an integrated circuit 218 coupled to said collector terminal 216 of said BJT 210 and said second junction 208; and (v) an n-channel metal-oxide-semiconductor field-effect transistor (MOSFET) 220, having a source terminal 222 and a drain terminal 224, said source terminal 222 coupled to said integrated circuit 218 and said drain terminal 224 coupled to the heating element 300 of the heated apparel system.

The heating elements 300 can be removable from the garment 100 or non-removable. In the preferred embodiment, in a jacket equipped with the system of the present invention, a heating element is secured on each front flap, back, each sleeve and collar portion. In a glove equipped with the system of the present invention, heating elements 300 are provided on a back side of the glove including the back side of the fingers but not on a palm or front side.

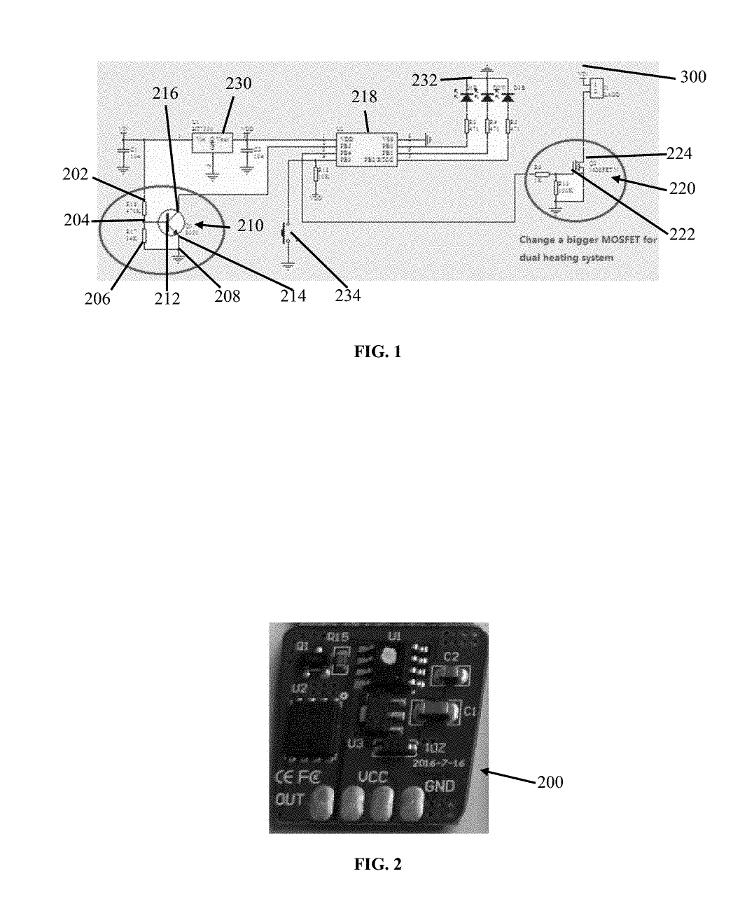

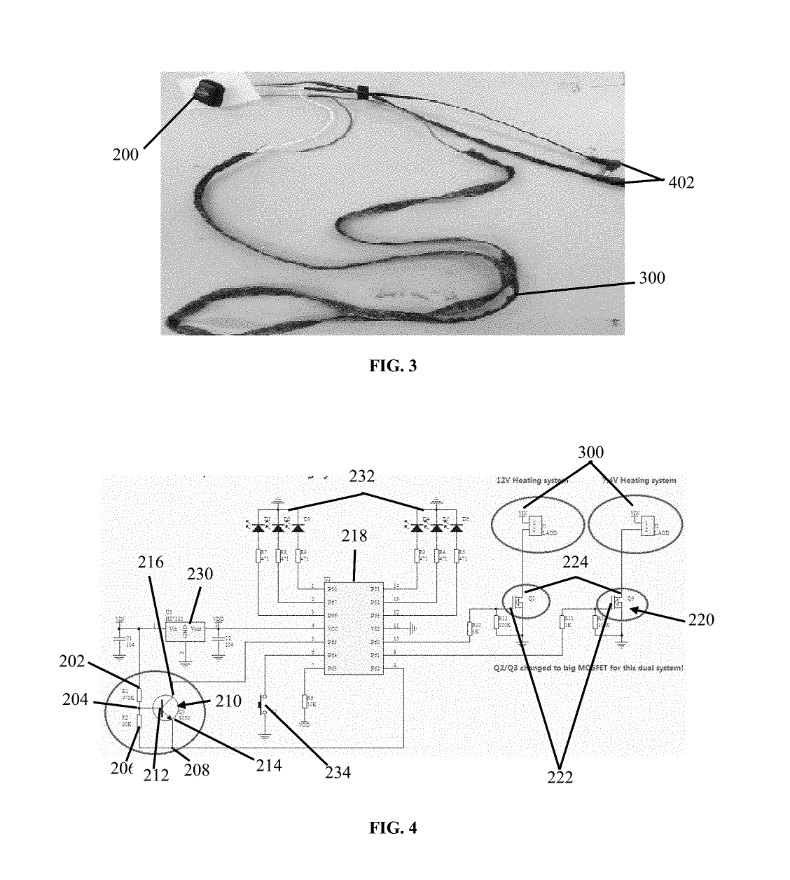

Referring to FIGS. 1-3, in a first embodiment, the first resistor 202 is a 470K-Ohm resistor and the second resistor 206 is a 34K-Ohm resistor. In conjunction with the BJT 210, the source voltage can be monitored to determine whether it is 12 volts or 7.4 volts. The MOSFET 220 can accommodate both voltages, allowing the heating element 300 to heat regardless of the source voltage. Due to the ability to use the heated apparel system with a lower 7.4 voltage, this embodiment is better suited for powering smaller heating elements such as those that may be used in gloves.

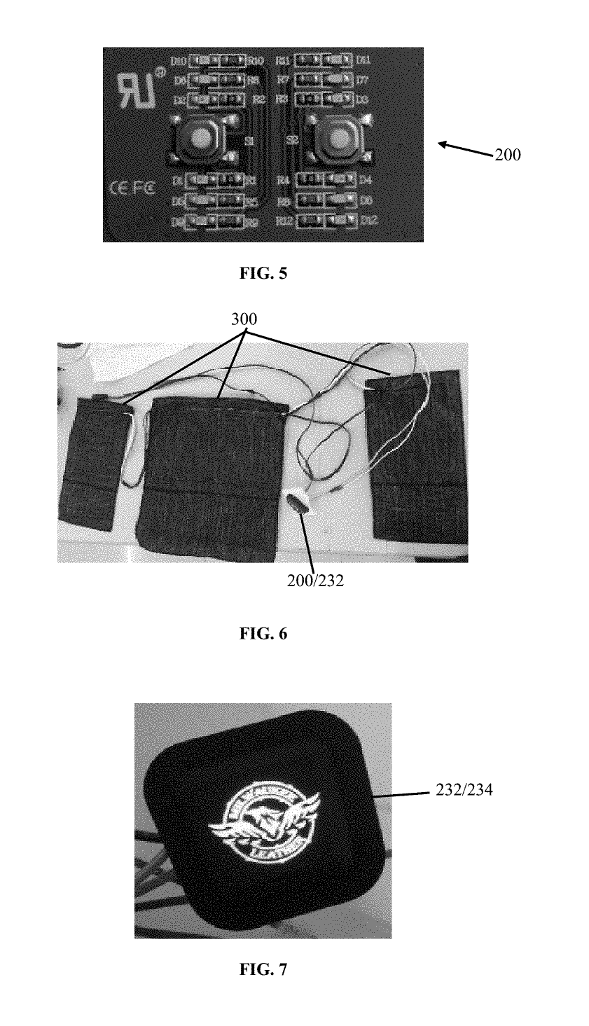

Referring to FIGS. 4-6, in a second embodiment, the first resistor 202 is a 470K-Ohm resistor and the second resistor 206 is a 30K-Ohm resistor. However, resistors with other resistances are possible to accommodate other voltages. In conjunction with the BJT 210, the source voltage can be monitored to determine whether it is 12 volts or 7.4 volts. This embodiment has a first MOSFET 220 coupled to a first heating element 300 and a second MOSFET 220 coupled to a second heating element 300. When the source voltage is 12 volts, only the first heating element 300 is enabled. In the preferred embodiment, the first heating element 300 is dedicated to the 12-volt sub-system and is located on and heats each front flap, back, each sleeve and collar portion.

In the preferred embodiment, when the source voltage is 7.4 volts, only the second heating element 300 is enabled. This allows the system to direct the more limited power to a subset of heating elements 300. The second heating element 300 is included on and heats only each front flap and back of the jacket. Gloves what are coupled to the system are configured to heat in either voltage scenario.

In the alternative, a single heating element could be provided throughout the jacket and the heated locations controlled by the system.

Alternatively, the heating elements 300 can be detachably coupled to disable some but not all of the heating elements 300 and facilitate replacement of heating elements 300. For example, heating elements 300 located on gloves can be detachably coupled to allow the system to be used with or without heated gloves attached.

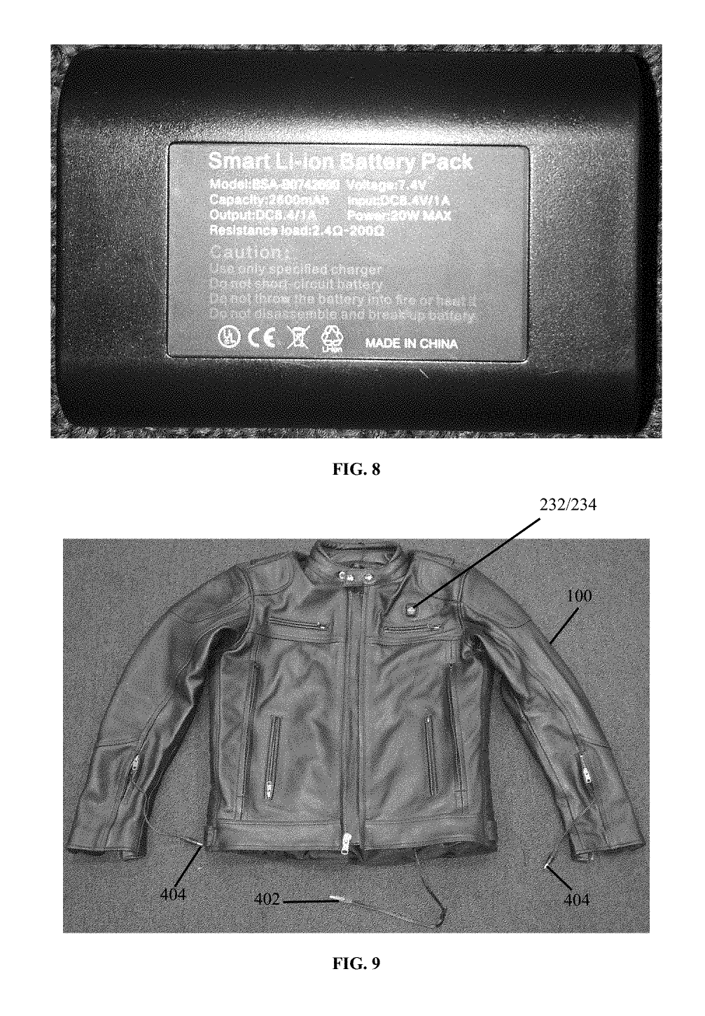

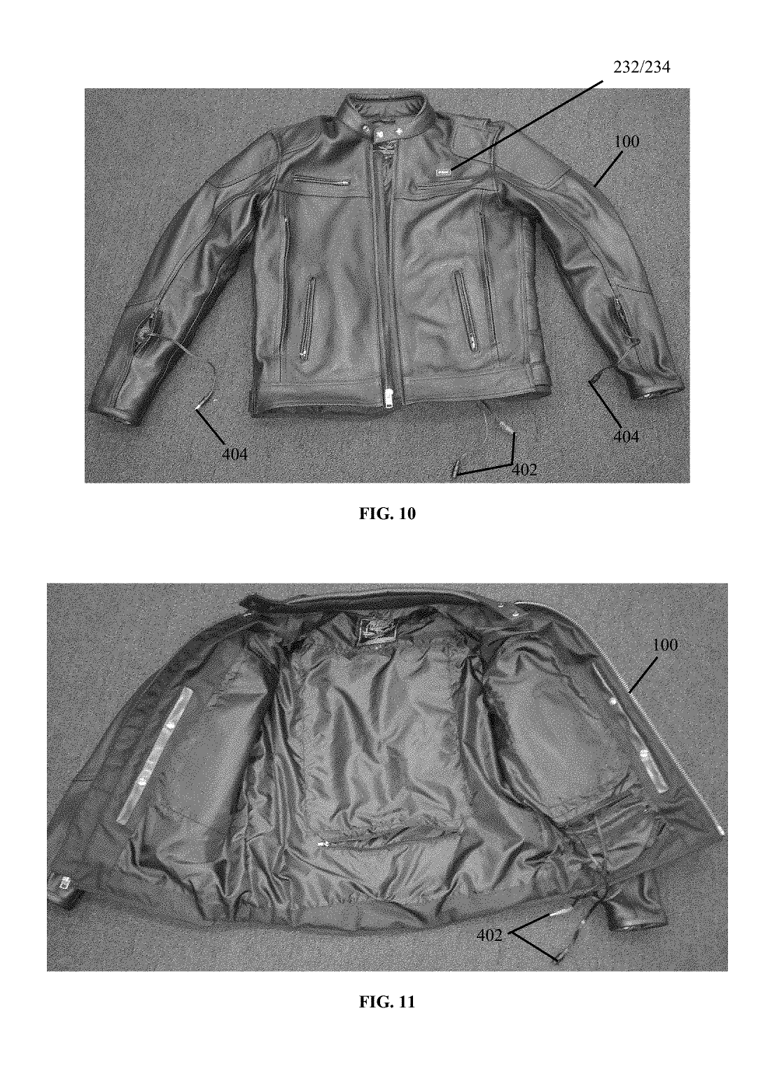

Referring to FIGS. 1 and 4, in the exemplar embodiment, a voltage regulator 230 is coupled to the integrated circuit 218 to provide power to other components such as LED lights located on a pushbutton 232, as shown in FIGS. 9 and 10.

Referring to FIGS. 1, 4, and 7, in the exemplar embodiment, a single switch 234 coupled to the integrated circuit 218 toggles the system on and off via the pushbutton/LED light 232, the LED light 232 illuminating a logo to indicate whether the system is on or off. In the preferred embodiment, the system of the present invention is configured such that multiple heating levels are available, the heating levels being controlled by the pushbutton 232.

In other embodiments, the switch 234, a plurality of switches, a touchscreen, or other means of user input can control the degree of heating desired, the areas to be heated, and LED lights and can indicate power by means of an LED light, display screen, or other feedback device.

Power is provided to the system by either a first power source or a second power source. In the exemplar embodiment, the first power source is a 12-volt motorcycle battery (not shown) and the second power source is a 7.4-volt portable rechargeable lithium-ion battery, as shown in FIG. 8. The 7.4-volt portable battery could be stored within the jacket, for example, in an inside pocket of the jacket.

Referring to FIG. 9, the first and second power sources can be connected to the system by an SAE or coaxial power connector 402 as commonly found on many motorcycles. Other power connectors, such as universal serial port (USB) and car cigarette lighter plug, are possible. Plug adapters can be used to provide connector compatibility. Auxiliary connectors 404 located on the sleeves can be connected to and power additional devices such as heated gloves.

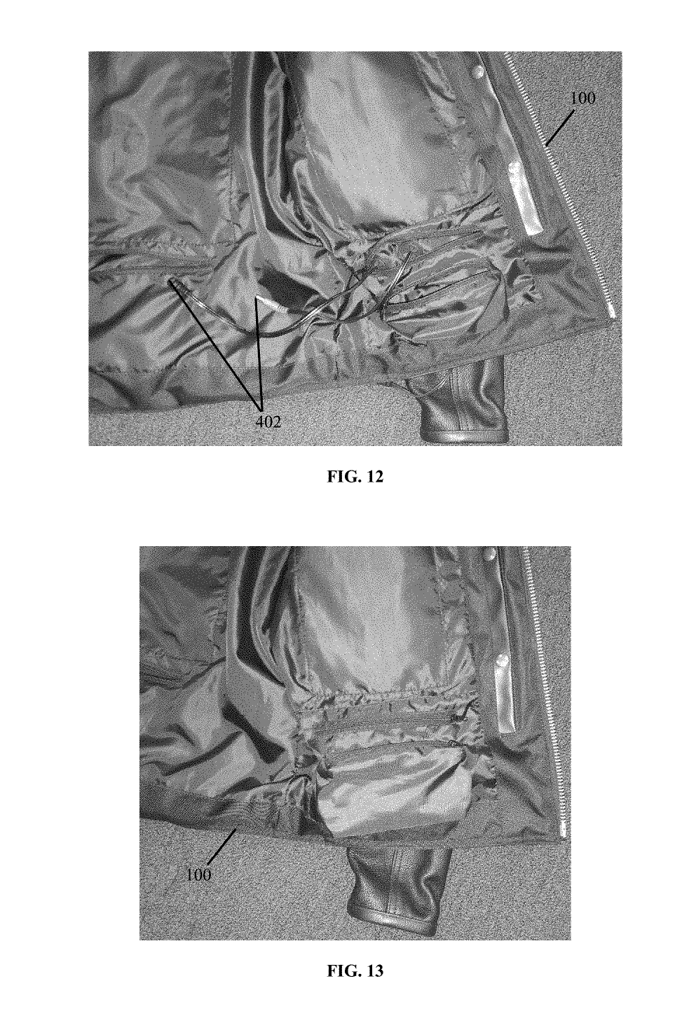

Referring to FIGS. 10-12, the first and second power sources can utilize two separate power connectors 402. The two connectors 402 can be differentiated by different colors or connection types. For example, the 12-volt connector 402 can be a female connector and the 7.4-volt connector 402 can be a male connector. Auxiliary connectors 404 located on the sleeves can be connected to and power additional devices such as heated gloves. In one embodiment, connecting both a 12-volt power source and a 7.4-volt power source can allow the system to be powered solely by the 12-volt power source while charging the 7.4-volt power source. This eliminates the need to recharge the 7.4-volt power source separately.

The ability to use both a 12-volt battery and a 7.4-volt portable battery enables the system to be heated by the longer-lasting 12-volt battery when the system is tethered to a vehicle and heated by the shorter-lasting 7.4-volt portable battery when the system is not tethered to the vehicle.

Referring to FIG. 9-13, the power connectors 402 and portable battery can be concealed in pockets on the garment 100. For example, the battery and power connectors 402 can be concealed in a zippered pocket located on the inside of a jacket, as shown in FIG. 13, and the auxiliary connectors 404 for gloves can be concealed in zippered pockets located on the outside of the jacket sleeves.

The present invention may be embodied in other specific forms without departing from its spirit or essential characteristics. The described embodiments are to be considered in all respects only as illustrative and not restrictive. The scope of the invention will be, therefore, indicated by claims rather than by the foregoing description. All changes, which come within the meaning and range of equivalency of the claims, are to be embraced within their scope.

What is claimed is:

1. A heated apparel system comprising:
a garment;
a control unit;
a heating element coupled to the control unit; and
a power source coupled to the heating element, wherein the control unit controls the heating element to heat the garment from power provided by the power source.

2. The heated apparel system of claim 1, wherein the control unit includes a printed circuit board (PCB).

3. The heated apparel system of claim 1, wherein the power source is a battery.

4. The heated apparel system of claim 1, wherein the power source is rechargeable.

5. The heated apparel system of claim 1, wherein the power source includes:
a first power source; and
a second power source;
wherein the heating unit is coupled to at least one of the first and second power sources.

6. The heated apparel system of claim 5, wherein the heating element includes:
a first heating element coupled to the first power source; and
a second heating element coupled to the second power source.

7. The heated apparel system of claim 1, wherein the control unit includes:
an integrated circuit; and
a transistor, coupled to the integrated circuit, the heating element, and the power source, with the transistor driven by the integrated circuit to selectively control the heating element to generate heat.

8. The heating system of claim 7, wherein the transistor includes an n-channel metal-oxide-semiconductor field-effect transistor (MOSFET) having a source terminal and a drain terminal, with the source terminal coupled to the integrated circuit and the drain terminal coupled to the heating element.

9. The heating apparel system of claim 8, wherein the control unit further comprises:
a first junction;
a second junction;
a first resistor coupled to the first junction;
a second resistor coupled to the first junction and the second junction; and
a negatively doped bipolar junction transistor (BJT) having a base terminal, an emitter terminal, and a collector terminal, the base terminal coupled to the first junction and the emitter terminal coupled to the second junction, with the integrated circuit coupled to the collector terminal of the BJT and the second junction;
wherein the integrated circuit and the BJT monitor a voltage of the source terminal to determine the available voltage from the power source to provide power to the heating element.

10. A garment comprising:
a garment material;
a control unit;
a heating element coupled to the control unit; and
a power source coupled to the heating element, wherein the control unit controls the heating element to heat the garment material from power provided by the power source.

11. The garment of claim 10, wherein the control unit includes a printed circuit board (PCB).

12. The garment of claim 10, wherein the power source is a battery.

13. The garment of claim 10, wherein the power source is rechargeable.

14. The garment of claim 10, wherein the power source includes:
a first power source; and
a second power source;
wherein the heating unit is coupled to at least one of the first and second power sources.

15. The garment of claim 14, wherein the heating element includes:
a first heating element coupled to the first power source; and
a second heating element coupled to the second power source.

16. The garment of claim 10, wherein the control unit includes:
an integrated circuit; and
a transistor, coupled to the integrated circuit, the heating element, and the power source, with the transistor driven by the integrated circuit to selectively control the heating element to generate heat.

17. The garment of claim 16, wherein the transistor includes an n-channel metal-oxide-semiconductor field-effect transistor (MOSFET) having a source terminal and a drain terminal, with the source terminal coupled to the integrated circuit and the drain terminal coupled to the heating element.

18. The garment of claim 17, wherein the control unit further comprises:
a first junction;
a second junction;
a first resistor coupled to the first junction;
a second resistor coupled to the first junction and the second junction; and
a negatively doped bipolar junction transistor (BJT) having a base terminal, an emitter terminal, and a collector terminal, the base terminal coupled to the first junction and the emitter terminal coupled to the second junction, with the integrated circuit coupled to the collector terminal of the BJT and the second junction;
wherein the integrated circuit and the BJT monitor a voltage of the source terminal to determine the available voltage from the power source to provide power to the heating element.

19. A method for heating a garment having a garment material, the method comprising:
providing a control unit, a heating element coupled to the control unit, and a power source coupled to the heating element;
controlling the heating element using the control unit; and
heating the garment material using the heating element from power provided by the power source.

20. The method of claim 19, further comprising:
providing an n-channel metal-oxide-semiconductor field-effect transistor (MOSFET) having a source terminal and a drain terminal, with the source terminal coupled to the control unit and the drain terminal coupled to the heating element; and
driving the MOSFET using the control unit to selectively control the heating element to generate heat.
